(19) United States
(12) Patent Application Publication
(10) Pub. No.: US 2024/0268041 A1
(43) Pub. Date: Aug. 8, 2024

(54) SECURITY CAGE FOR COMPUTER SERVERS

(71) Applicant: COLO SECURITY CAGE LLC, Carnegie, PA (US)

(72) Inventors: Timothy J. Keefe, Carnegie, PA (US); Nathan Carilli, Millsboro, PA (US); James H. Collins, Pittsburgh, PA (US); Mathiam Rajakovic, Charleroi, PA (US)

(73) Assignee: COLO SECURITY CAGE LLC, Camegie, PA (US)

(21) Appl. No.: 18/105,613

(22) Filed: Feb. 3, 2023

(51) Int. Cl. H05K 5/02; H05K 7/14

(52) U.S. Cl. CPC H05K 5/0208; H05K 7/1488

(57) ABSTRACT

A physical security cage for computer server racks which includes a front end panel having a medial vertically movable personnel access door; a rear end panel positioned in spaced longitudinal relation to the rear end panel; a first vertically movable lateral access panel extending between the front end panel and the rear end panel; a second vertically movable lateral access panel extending between the front end panel and rear end panel in spaced parallel relation to the first vertically movable lateral access panel. A first row of computer server racks are positioned adjacent the first vertically movable lateral access panel and a second of row of computer server racks are positioned adjacent the second vertically movable lateral access panel. An interior personnel access space is interposed between the first row of computer server racks and the second row of computer server racks.

### FIELD OF THE INVENTION

The present invention relates to infrastructure for computer hardware and more particularly to cages used to provide physical security for computer servers.

### BACKGROUND OF THE INVENTION

A server is a core computer which performs tasks for other computers in a network system. Servers may provide functions such as storage and printing, and they can provide a variety of functions for network users, such as storage and printing, and can also be used for sharing resources among the clients in the network system. A basic architecture of the server may be similar to that of an ordinary personal computer. The server includes a central processing unit (CPU), a memory, a hard drive, and input and output devices, which are connected by a bus inside. A bridge chip may connect the CPU and the memory. Another bridge chip may connect the input and the output devices.

A widely used server is a rack server. A rack server, also known as a rack mount server, rack-mounted server or rack mount computer, is a computer designed to be situated in a rectangular structure called a server rack. The advantages of a server rack include better space conservation for rack servers, increased scalability, maximized air flow when coupled with a cooling system and ease of regular computer maintenance and diagnostics, given that their design allows technicians and operators to easily slide rack servers in and out of them.

Mechanically, rack servers are able to slide in and out of a server rack with ease. This feature has advantages in that it allows systems administrators, technicians and operators to diagnose technical problems and hot-swap parts without shutting down and disassembling the entire system. Such a feature is vital to mission-critical programs and applications, in which lengthy periods of downtime could have detrimental effects.

In order to provide physical security for server racks, they are conventionally housed in a security cage. A conventional prior art server rack cage is shown in FIG. 1. Referring to FIG. 1, a conventional cage would typically include a front panel 10, a rear panel 12, and opposed lateral panels 14 and 16. These panels would typically enclose server rack as at racks 18, 20, 22, 24 and 26. On the front panel a door 28 would typically be mounted on hinges as at hinge 30 so that the door may pivot outwardly from the front panel to allow access to the interior of the cage to permit serving of the servers through opening 32. It will be seen that as the door pivots outwardly a floor space as at front exterior space 34 is required to allow access to the interior of the cage. There is also a considerable amount of interior floor space as at front interior floor space 36, rear interior floor space 38, and lateral interior floor spaces 40 and 42. Floor space in a data room often is often relatively expensive. Accordingly, the necessity of providing the data room floor space for the door to pivot open to allow access to the servers in the interior of the cage may add considerable extra expense to the task of storing and securing the servers. The interior access spaces, particularly the front and rear interior floor spaces, may also add significant extra floor space in the data room which also adds to the expense of storing and securing the servers. For example, as is common, the front and rear end of the cage area 14 feet and the sides 18 feet in length and the server racks occupy 40 square feet, 212 square feet of often expensive data room floor space are being used for the server security cage, much of which may not be particularly productive.

It will, therefore, be appreciated that a need exists for a way to reduce the amount of floor space which is required for a server security cage.

### SUMMARY OF THE INVENTION

In the present invention a physical security cage for computer rack servers is provided which minimizes the amount of data room flooring includes a front end panel having a medial vertically movable personnel access door; a rear end panel positioned in spaced longitudinal relation to the rear end panel; a first vertically movable lateral access panel extending between the front end panel and the rear end panel; a second vertically movable lateral access panel extending between the front end panel and rear end panel in spaced parallel relation to the first vertically movable lateral access panel. A first row of computer server racks are positioned adjacent the first vertically movable lateral access panel and a second of row of computer server racks are positioned adjacent the second vertically movable lateral access panel. An interior personnel access space is interposed between the first row of computer server racks and the second row of computer server racks.

The features and advantages described herein are not all-inclusive and, in particular, many additional features and advantages will be apparent to one of ordinary skill in the art in view of the drawings, specification, and claims. Moreover, it should be noted that the language used in the specification has been principally selected for readability and instructional purposes, and not to limit the scope of the inventive subject matter.

### BRIEF DESCRIPTION OF THE DRAWINGS

The invention is further described with reference to the accompanying drawings wherein:

FIG. 1 is a schematic top plan view of a conventional prior art server rack cage;

FIG. 2 is top plan view of a preferred embodiment of the server rack cage of the present invention;

FIG. 3 is a front end view of the server rack cage shown in FIG. 2;

FIG. 4 is a side view of the of the server rack cage shown in FIG. 2;

FIG. 5 is a perspective view of the server rack cage shown in FIG. 2;

FIG. 6 is top plan view of the server rack cage shown in FIG. 2 in which server racks are enclosed;

FIG. 7 is a front end view of the server rack cage with server racks shown in FIG. 6;

FIG. 8 is a side view of the of the server rack cage with server racks shown in FIG. 6;

FIG. 9 is a perspective view of the server rack cage with server racks shown in FIG. 6;

FIG. 10 is top plan view of a second preferred embodiment of the server rack cage of the present invention;

FIG. 11 is a front end view of the server rack cage shown in FIG. 10;

FIG. 12 is a side view of the of the server rack cage shown in FIG. 10;

FIG. 13 is a perspective view of the server rack cage shown in FIG. 10;

FIG. 14 is top plan view of the server rack cage shown in FIG. 10 in which server racks are enclosed;

FIG. 15 is a front end view of the server rack cage with server racks shown in FIG. 14;

FIG. 16 is a side view of the of the server rack cage with server racks shown in FIG. 14; and

FIG. 17 is a perspective view of the server rack cage with server racks shown in FIG.

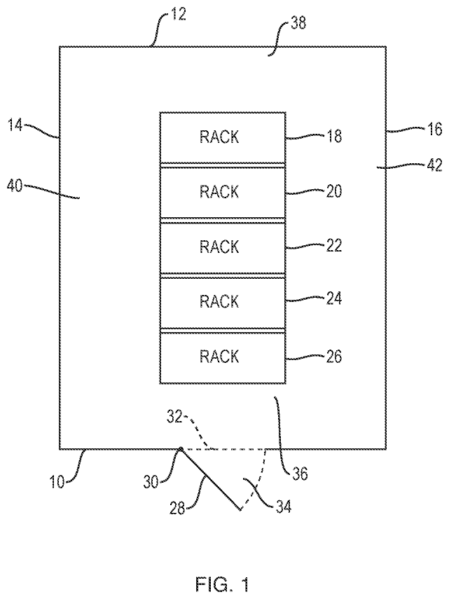

### DETAILED DESCRIPTION

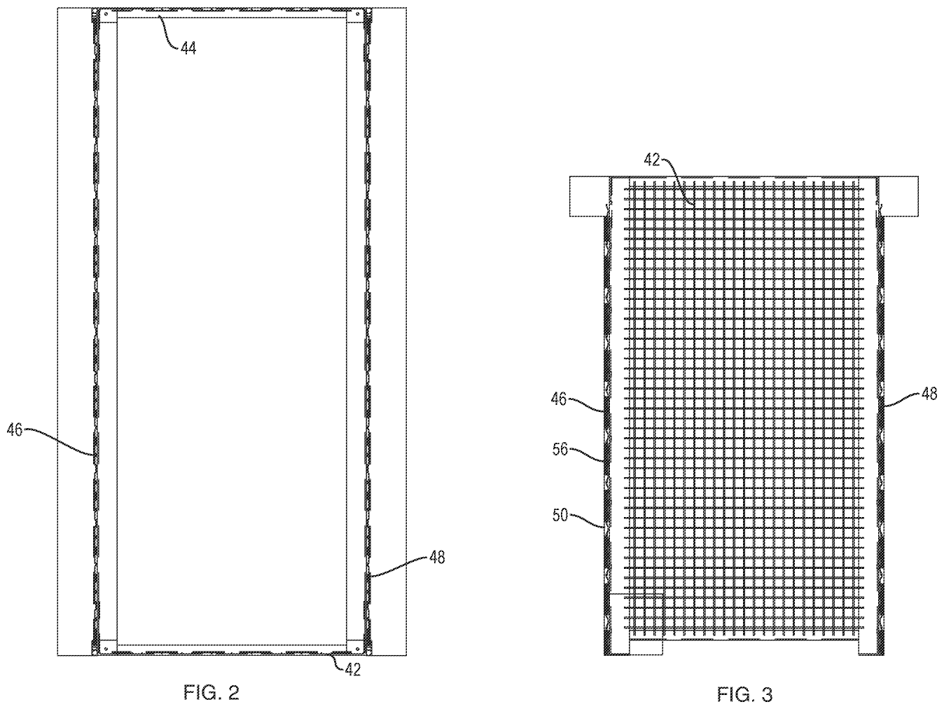

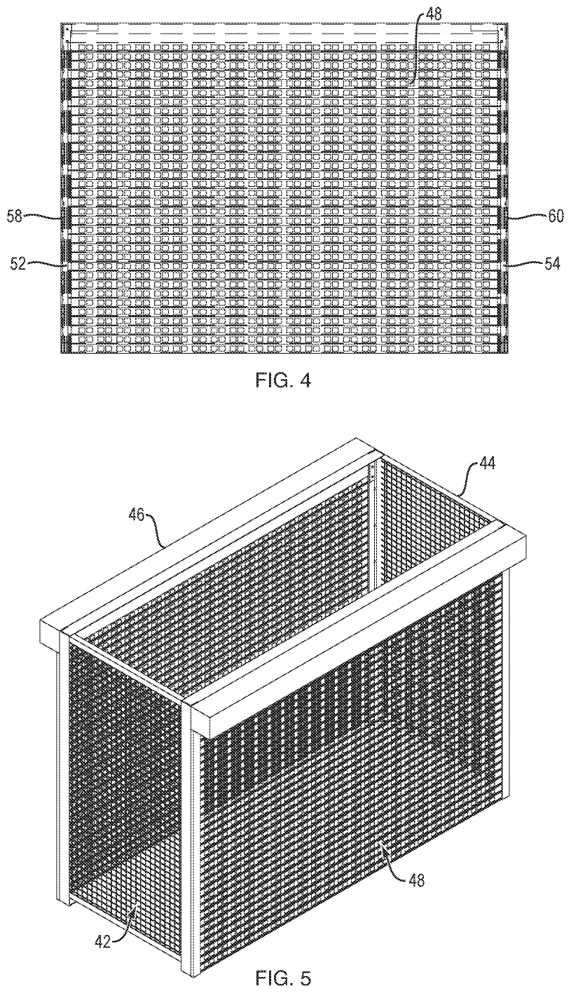

Referring to FIGS. 2-5, a first embodiment of the cage of the present invention is shown without servers. This cage includes a front end panel 42, a rear end panel 44, and a pair of opposed lateral roll-up server access panels 46 and 48. On the opposed ends of the lateral roll up access panel 46 there is a vertical rail 50 and another vertical rail (not shown). Adjacent the opposed ends of the lateral roll up access panel 46 mounted on the front end panel there is a vertical rail 50 and another vertical rail (not shown) mounted on the rear end panel. Adjacent the opposed ends of the lateral roll up access panel 48 there are vertical rails 52 and 54 which are mounted respectively on the front panel and rear panel. A plurality of vertically aligned wheels as at wheel 56 are mounted on lateral roll up panel 46 to allow that panel to be moveable vertically upwardly and then downwardly on its adjacent vertical rails. A plurality of vertically aligned wheels as at wheels 58 and 60 are mounted on lateral roll up panel 48 to allow that panel to be moveable vertically upwardly and then downwardly respectfully on its adjacent vertical rails 52 and 54.

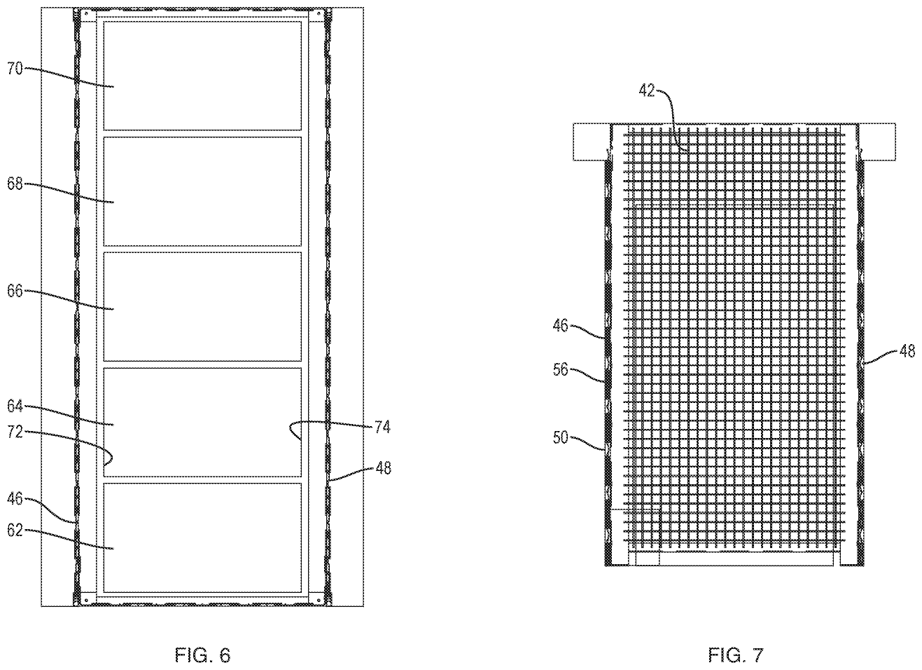

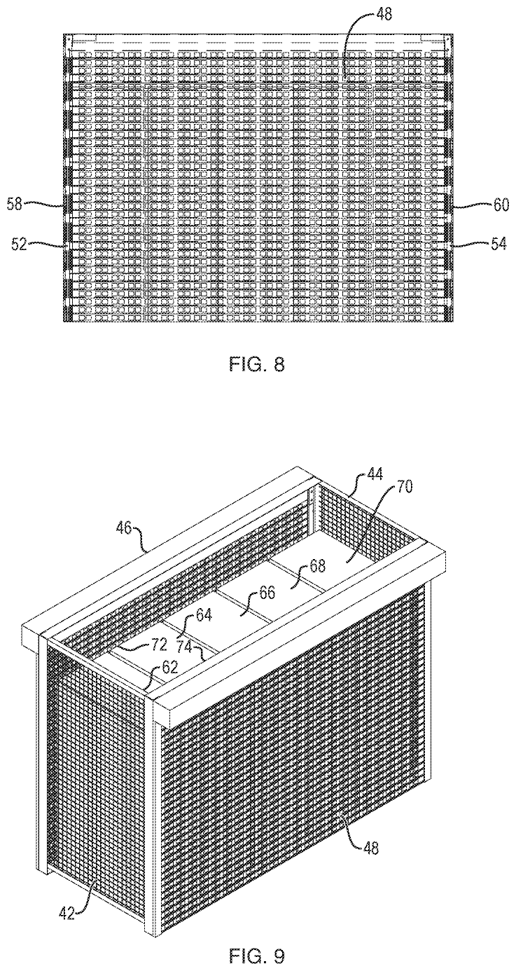

Referring to FIGS. 6-9, the first preferred embodiment the cage of the present invention is shown housing rack servers. As explained above, the cage includes a front end panel 42, a rear end panel 44, and a pair of opposed lateral roll-up server access panels 46 and 48. On the opposed ends of the lateral roll up access panel 46 there is a vertical rail 50 and another vertical rail (not shown). Adjacent the opposed ends of the lateral roll up access panel 46 mounted on the front end panel there is a vertical rail 50 and another vertical rail (not shown) mounted on the rear end panel. Adjacent the opposed ends of the lateral roll up access panel 48 there are vertical rails 52 and 54 which are mounted respectively on the front panel and rear panel. A plurality of wheels vertically aligned as at wheel 56 are mounted on lateral roll up panel 46 to allow that panel to be moveable vertically upwardly and then downwardly on its adjacent vertical rails. A plurality of vertically aligned wheels as at wheels 58 and 60 are mounted on lateral roll up panel 48 to allow that panel to be moveable vertically upwardly and then downwardly respectfully on its adjacent vertical rails 52 and 54. Within the cage a plurality of rack servers as at 56, 58, 60, 62, and 64 are mounted in server racks. Each of these servers has opposed access faces as at 66 and 68 on server 58. It will be appreciated that lateral roll up access panel 46 can be moved vertically upwardly on its wheels as at 56 on the adjacent rails as at 50 to allow access to the rack servers 62, 64, 66, 68, and 70 at their access faces as at access face 76. It will also be appreciated that lateral roll up access panel 48 can be moved vertically upwardly on its wheels as at 58 and 60 respectively on the adjacent rails 52 and 54 to allow access to the same rack servers at their opposed access faces as at access face 74.

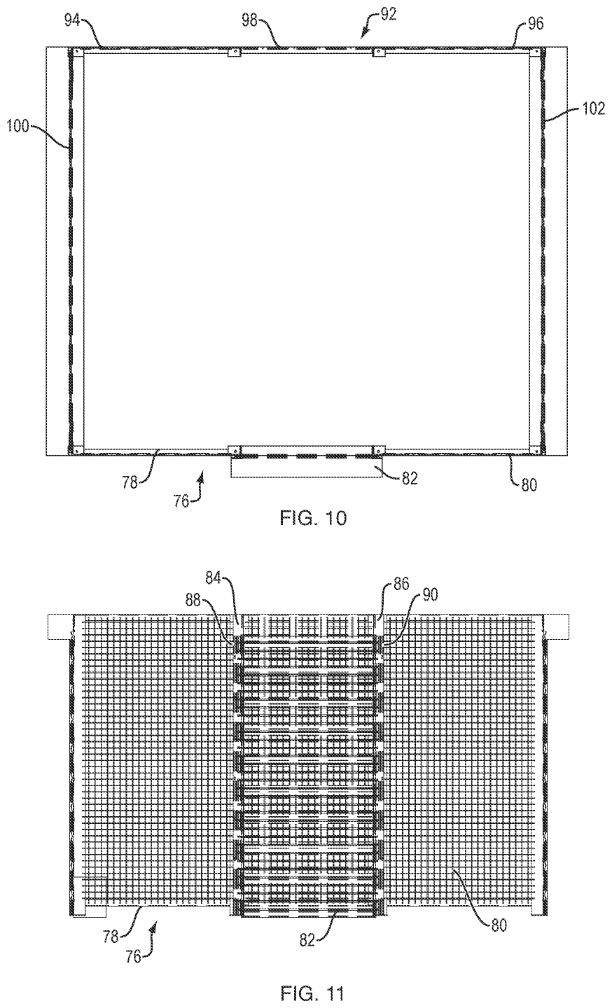

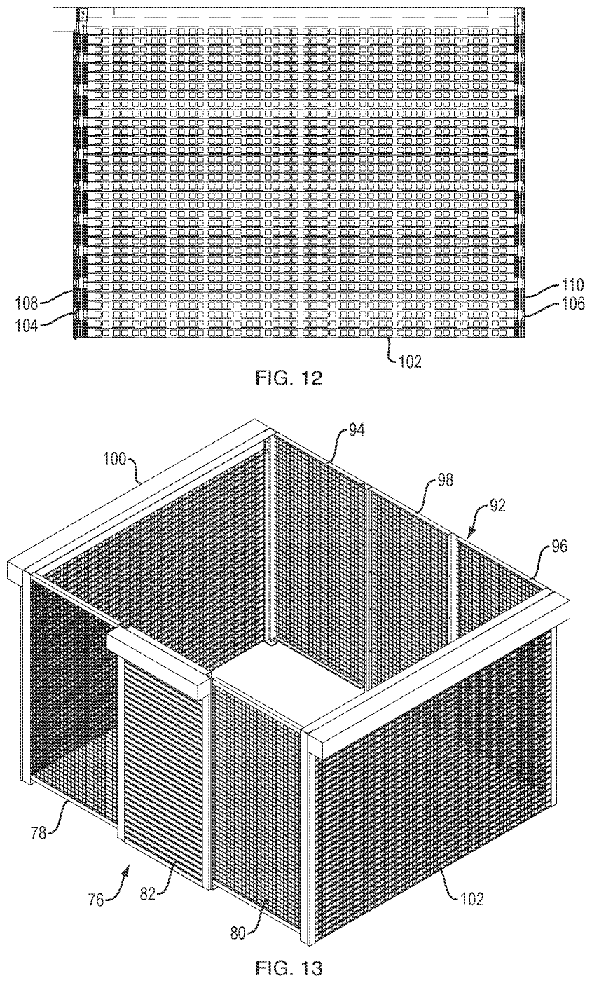

Referring to FIGS. 10-13, an alternate embodiment of the invention is shown which is suitable for containing multiple rows of rack servers. This cage includes a front end generally at 76 which is comprised of opposed standard end panels 78 and 80 with a roll up personnel access gate 82 interposed between the standard end panels. The personnel access gate is moveable up and down vertically on vertical rails 84 and 86 mounted respectively on end panels 78 and 80 by means of wheels as at 88 and 90 on the personnel access gate. The cage also includes a rear end generally at 92 which includes opposed end panels 94 and 96 with a standard filler panel 98 interposed between these end panels. The cage also includes opposed lateral roll up access panes 100 and 102 which are moveable up and down vertically to allow access to the interior of the cage. The roll up access panel 102 moves vertically up and down on vertical rails 104 and 106 fixed respectfully on panels 80 and 96 by means of wheels 108 and 110 which travel respectively on rails 104 and 106. The roll up access panel is moveable up and down vertically in the same manner on vertical rails (not shown) and wheels (not shown).

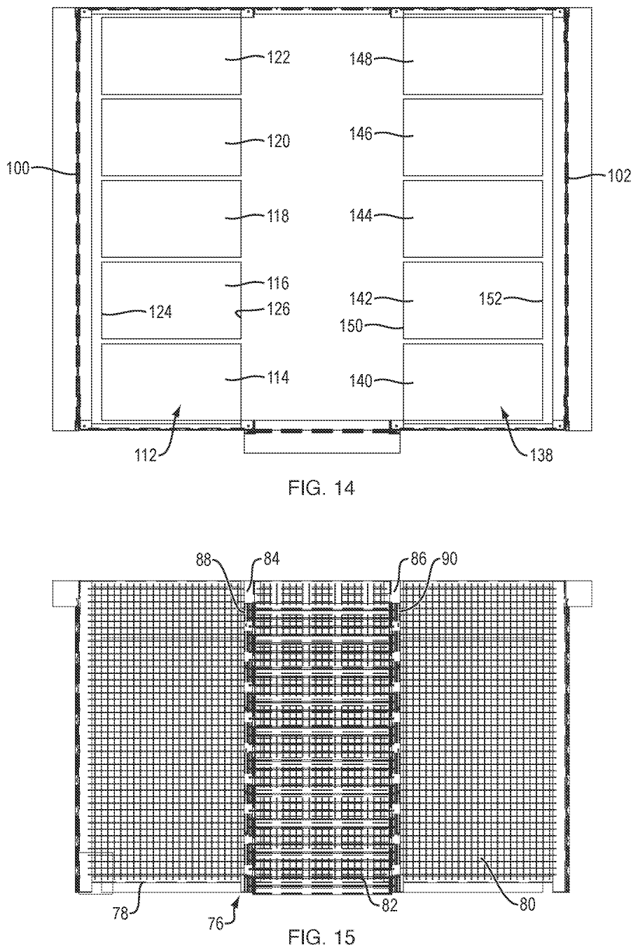

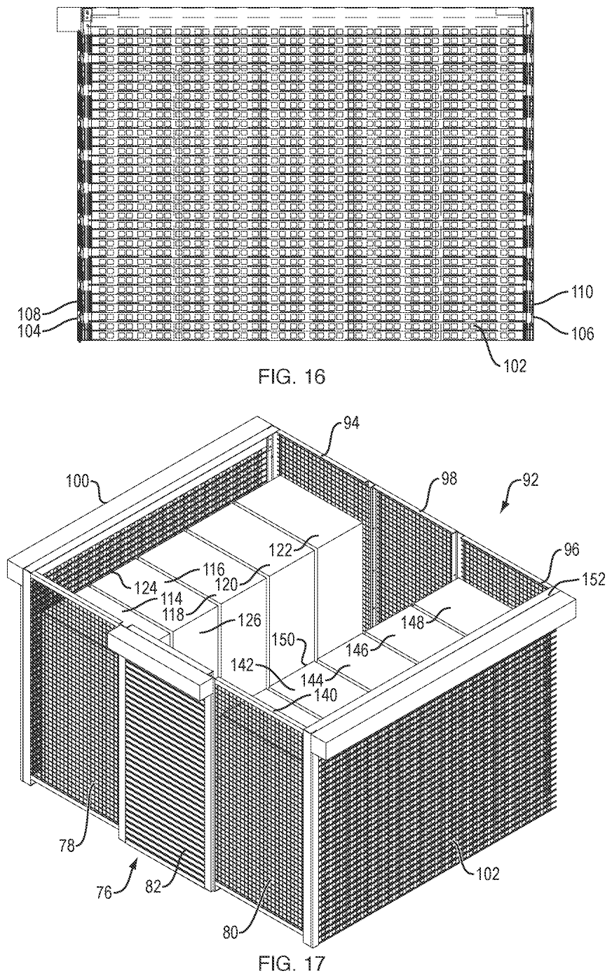

Referring to FIGS. 14-17, the alternate embodiment of the cage of the invention is shown in which it secures a number of rack servers. As described above, this cage includes a front end generally at 76 which is comprised of opposed standard end panels 78 and 80 with a roll up personnel access gate 82 interposed between the standard end panels. The gate 82 is moveable vertically in the way described above by means of wheels as at 88 and 90 moving on vertical rails 82. The cage also includes a rear end generally at 92 which includes opposed end panels 94 and 96 with a standard filler panel 98 interposed between these end panels. The cage also includes opposed roll up access panels 100 and 102 which are moveable up and down vertically to allow access to the interior of the cage by means of wheels as at 108 and 110 which are moveable on vertical rails 104 and 106. Adjacent the lateral roller access panel 100 and between the end panel 78 on the front end 76 and the end panel 94 on the rear end 92 there is a row 112 of rack servers 114, 116, 118, 120, and 122. Each of these rack servers has a pair of opposed access faces as at outer access face 124 and inner access face 126 on rack server 116. Adjacent the access panel 102 and between the end panel 80 on the front end 76 and the end panel 96 on the rear end 92 there is another row 138 of rack servers 140, 142, 144, 146, and 148. Each of these rack servers has a pair of opposed access faces as at outer access face 150 and inner access face 152 on rack server 142. Between the rows of rack servers 112 and 122 there is a medial access space 154. The personnel access gate 82 moves vertically upwardly to allow personnel to enter this medial access space to allow personnel to have access to the inner access faces of the rack servers in both row 112 and row 138. The roll up access panel 100 moves vertically to allow access to the outer access faces of the rack servers in row 112. Similarly, the roll up access panel 102 moves vertically to allow access to the outer access faces of the rack servers in row 138. After such access to the rack servers has been gained, the personnel access gate and the roll up access panels may be lowered to allow the servers in the interior of the cage to be again secured. As with the first embodiment, it will be appreciated that in this embodiment a significant amount of data room floor space is saved by using this arrangement.

The foregoing description of the embodiments of the invention has been presented for the purposes of illustration and description. It is not intended to be exhaustive or to limit the invention to the precise form disclosed. Many modifications and variations are possible in light of this disclosure. It is intended that the scope of the invention be limited not by this detailed description, but rather by the claims appended hereto.

What is claimed is:

1. A physical security cage for computer server racks comprising:
a front end panel;
a rear end panel positioned in spaced longitudinal relation to the rear end panel;
a first vertically movable lateral access panel extending between the front end panel and the rear end panel;
a second vertically movable lateral access panel extending between the front end panel and rear end panel in spaced parallel relation to the first vertically movable lateral access panel.

2. The computer server physical security cage of claim 1 wherein at least one computer security rack is interposed between the first vertically movable lateral access panel and the second 2 vertically movable lateral access panel.

3. The computer server physical security cage of claim 2 wherein the computer server rack has a first accessed face adjacent the first vertically movable lateral access panel.

4. The computer server physical security cage of claim 3 wherein the computer server rack has a second accessed face in opposed relation to the first access face and adjacent the second vertically movable lateral access panel.

5. The computer server physical security cage of claim 4 wherein there are a plurality of computer server racks interposed between the first vertically movable lateral access panel and the second vertically movable lateral access panel.

6. The computer server physical security cage of claim 5 wherein each of the plurality of computer server racks has a first accessed face adjacent the first vertically movable lateral access panel.

7. The computer server physical security cage of claim 6 wherein each of the plurality of computer server racks has a second accessed face adjacent the second vertically movable access panel.

8. The computer server physical security cage of claim 7 wherein the first vertically movable access panel has at least one set of aligned wheels which are moveable on a vertical rail to allow the first access panel to be moved upwardly to allow access to the first accessed faces of the server racks and to then be moved downwardly to secure the server rack.

9. The computer server physical security cage of claim 8 wherein the second vertically movable access panel has at least one set of aligned wheels which are moveable on a vertical rail to allow the second vertically moveable access panel to be moved upwardly to allow access to the first accessed faces of the server racks and to then be moved downwardly to secure the server rack.

10. A physical security cage for computer server racks comprising a front end panel having a medial vertically movable personnel access door; a rear end panel positioned in spaced longitudinal relation to the rear end panel; a first vertically movable lateral access panel extending between the front end panel and the rear end panel; a second vertically movable lateral access panel extending between the front end panel and rear end panel in spaced parallel relation to the first vertically movable lateral access panel.

11. The computer server physical security cage of claim 10 wherein a plurality of computer server racks in a first row of computer server racks are positioned adjacent the first vertically movable lateral access panel and a plurality of computer server racks in a second of row of computer server racks are positioned adjacent the second vertically movable lateral access panel and an interior personnel access space is interposed between the first row of computer server racks and the second row of computer server racks.

12. The computer server physical security cage of claim 11 wherein the medial vertically movable personnel access door is positioned on the front end panel to be aligned with the interior personnel access space.

13. The computer server physical security cage of claim 12 wherein the computer server racks in the first row of computer server racks each has an outer accessed face adjacent the first vertically movable lateral access panel and an inner accessed face adjacent the interior personnel access space.

14. The computer server physical security cage of claim 13 wherein the computer server racks in the second row of computer server racks each has a first accessed face adjacent the first vertically movable lateral access panel and a second accessed face adjacent the interior personnel access space.

15. The computer server physical security cage of claim 14 wherein the personnel access door has at least one set of aligned wheels which are moveable on a vertical rail to allow the personnel access door to be moved upwardly to egress to the interior personnel access space and to then be moved downwardly to secure the server racks in the first and second rows of server racks

16. The computer server physical security cage of claim 15 wherein the first vertically movable access panel has at least one set of aligned wheels which are moveable on a vertical rail to allow the first access panel to be moved upwardly to allow access to the first accessed faces of the server racks and to then be moved downwardly to secure the server racks in the first and second rows of server racks.

17. The computer server physical security cage of claim 16 wherein the second vertically movable access panel has at least one set of aligned wheels which are moveable on a vertical rail to allow the second access panel to be moved upwardly to allow access to the outer accessed faces of the server racks in the second row of access panels and to then be moved downwardly to secure the server racks in the first and second rows of server racks.

18. A physical security cage for computer server racks comprising a front end panel having a personnel access door; a rear end panel positioned in spaced longitudinal relation to the rear end panel; a first vertically movable lateral access panel extending between the front end panel and the rear end panel; a second vertically movable lateral access panel extending between the front end panel and rear end panel in spaced parallel relation to the first vertically movable lateral access panel; a plurality of rows of computer server racks each extending between the front end panel and rear end panel in spaced parallel relation to each other, wherein one of said rows is positioned so that one of its access faces are adjacent the first vertically movable lateral access panel and another of said rows is positioned so that one of its access faces is adjacent the second vertically movable lateral access.

19. The computer server physical security cage of claim 18 wherein the personnel access door has at least one set of aligned wheels which are moveable on a vertical rail to allow the spaced parallel rows of server racks.

20. The computer server physical security cage of claim 18 wherein the first and second vertically movable access panels each have at least one set of aligned wheels which are moveable on a vertical rail to allow the first and second access panels to be moved upwardly and downwardly.
